(19) United States
(12) Patent Application Publication
(10) Pub. No.: US 2025/0151426 A1
(43) Pub. Date: May 8, 2025

(54) IMAGE SENSOR

(71) Applicant: Samsung Electronics Co., Ltd., Suwon-si (KR)

(72) Inventors: Changkyu Lee, Suwon-si (KR); Jinyoung Kim, Suwon-si (KR); Byoungho Kwon, Suwon-si (KR); Jihun Lim, Suwon-si (KR)

(21) Appl. No.: 18/782,845

(22) Filed: Jul. 24, 2024

(30) Foreign Application Priority Data
Nov. 2, 2023 (KR) 10-2023-0150282

(51) Int. Cl. H01L 27/146

(52) U.S. Cl. CPC H10F 39/8023; H10F 39/011; H10F 39/182; H10F 39/80373; H10F 39/811; H10F 39/8053; H10F 39/8063; H10F 39/809

(57) ABSTRACT

An image sensor includes a substrate, a unit pixel region in the substrate, the unit pixel region including a photoelectric conversion region, a pixel isolation structure defining the unit pixel region, a first insulation layer on a front-side surface of the substrate, and a dual transfer gate electrode including a first sub transfer gate electrode and a second sub transfer gate electrode adjacent to each other in a horizontal direction each passing through the first insulation layer and buried in the substrate, in the unit pixel region, wherein a lower surface of each of the first and the second sub transfer gate electrode is disposed at a lower vertical level than an upper surface of the first insulation layer, and at a higher or equal vertical level than a lower surface of the first insulation layer.

### CROSS-REFERENCE TO RELATED APPLICATION

This application is based on and claims priority under 35 U.S.C. § 119 to Korean Patent Application No. 10-2023-0150282, filed on Nov. 2, 2023, in the Korean Intellectual Property Office, the disclosure of which is incorporated by reference herein in its entirety.

### BACKGROUND

Aspects of the inventive concept relate to an image sensor, and more particularly, to an image sensor including a photodiode.

Image sensors are devices which convert an optical image signal into an electrical signal. Image sensors include a plurality of pixels which receive incident light to convert the received light into an electrical signal and each include a photodiode region. Because the size of each pixel decreases as the degree of integration of image sensors increases, an electrical connection component of a pixel circuit for driving each pixel decreases and noise occurs, or photoelectric conversion efficiency such as a conversion gain is reduced.

### SUMMARY

Aspects of the inventive concept provide an image sensor having enhanced performance and reliability.

An image sensor according to an embodiment is provided. An image sensor according to an embodiment includes a substrate including a front-side surface and a backside surface opposite thereto, a unit pixel region disposed in the substrate, the unit pixel region including a photoelectric conversion region, a pixel isolation structure defining the unit pixel region, extending in a vertical direction in the substrate, and extending in a first horizontal direction and a second horizontal direction, a first insulation layer disposed on the front-side surface of the substrate, and a dual transfer gate electrode including a first sub transfer gate electrode and a second sub transfer gate electrode adjacent to each other in the first horizontal direction each passing through the first insulation layer and accordingly buried in the substrate, in the unit pixel region, wherein a lower surface of each of the first sub transfer gate electrode and the second sub transfer gate electrode is disposed at a vertical level which is lower than an upper surface of the first insulation layer, and the lower surface of each of the first sub transfer gate electrode and the second sub transfer gate electrode is disposed at a vertical level which is higher than or equal to a lower surface of the first insulation layer.

An image sensor according to an embodiment is provided. An image sensor according to an embodiment includes a substrate including a front-side surface and a backside surface opposite thereto, a unit pixel region disposed in the substrate, the unit pixel region including a first sub photoelectric conversion region and a second sub photoelectric conversion region, a pixel isolation structure defining the unit pixel region, extending in a vertical direction in the substrate, and extending in a first horizontal direction and a second horizontal direction, an insulation layer disposed on the front-side surface of the substrate, a first dual transfer gate electrode disposed in the substrate to pass through the insulation layer and correspond to the first sub photoelectric conversion region, in the unit pixel region, and a second dual transfer gate electrode disposed in the substrate to pass through the insulation layer and correspond to the second sub photoelectric conversion region, in the unit pixel region, the first dual transfer gate electrode includes a first sub transfer gate electrode and a second sub transfer gate electrode adjacent thereto, in the substrate, the second dual transfer gate electrode includes a third sub transfer gate electrode and a fourth sub transfer gate electrode adjacent thereto, in the substrate, each of the first sub transfer gate electrode, the second sub transfer gate electrode, the third sub transfer gate electrode, and the fourth sub transfer gate electrode includes at least a portion which is not buried in the substrate, and a lower surface of each of the first sub transfer gate electrode, the second sub transfer gate electrode, the third sub transfer gate electrode, and the fourth sub transfer gate electrode is disposed at a vertical level which is higher than or equal to a lower surface of the insulation layer.

An image sensor according to an embodiment is provided. An image sensor according to an embodiment includes a substrate including a front-side surface and a backside surface opposite thereto, a unit pixel region disposed in the substrate, the unit pixel region including a first sub photoelectric conversion region and a second sub photoelectric conversion region, a pixel isolation structure defining the unit pixel region, extending in a vertical direction in the substrate, and extending in a first horizontal direction and a second horizontal direction, a first insulation layer and a second insulation layer sequentially arranged on the front-side surface of the substrate, a first dual transfer gate electrode disposed in the substrate to pass through the first insulation layer and correspond to the first sub photoelectric conversion region, in the unit pixel region, a second dual transfer gate electrode disposed in the substrate to pass through the first insulation layer and correspond to the second sub photoelectric conversion region, in the unit pixel region, a plurality of conductive vias passing through the second insulation layer and contacting each of the first dual transfer gate electrode and the second dual transfer gate electrode, and a color filter and a lens each disposed on the backside surface of the substrate, the first dual transfer gate electrode includes a first sub transfer gate electrode and a second sub transfer gate electrode adjacent thereto, in the substrate, the second dual transfer gate electrode includes a third sub transfer gate electrode and a fourth sub transfer gate electrode adjacent thereto, in the substrate, the first dual transfer gate electrode and the second dual transfer gate electrode include a material having an etch selectivity corresponding to the first insulation layer, a lower surface of each of the first sub transfer gate electrode, the second sub transfer gate electrode, the third sub transfer gate electrode, and the fourth sub transfer gate electrode is disposed at a vertical level which is lower than the front-side surface of the substrate, and an upper surface of each of the first sub transfer gate electrode, the second sub transfer gate electrode, the third sub transfer gate electrode, and the fourth sub transfer gate electrode is disposed at a vertical level which is higher than the front-side surface of the substrate.

### BRIEF DESCRIPTION OF THE DRAWINGS

Embodiments will be more clearly understood from the following detailed description taken in conjunction with the accompanying drawings in which:

FIG. 1 is a perspective view schematically illustrating an image sensor according to embodiments;

FIG. 2 is a layout view illustrating an image sensor corresponding to one pixel of FIG. 1;

FIG. 3 is a cross-sectional view taken along line A-A of FIG. 2;

FIG. 4 is a cross-sectional view taken along line B-B of FIG. 2;

FIG. 5 is an enlarged cross-sectional view of a region EX1 of FIG. 3;

FIGS. 6 and 7 are enlarged cross-sectional views of an image sensor according to embodiments;

FIG. 8 is an equivalent circuit diagram of an image sensor according to embodiments;

FIG. 9 is a layout view illustrating an image sensor according to embodiments;

FIG. 10 is a perspective view schematically illustrating an image sensor according to embodiments;

FIG. 11 is a cross-sectional view taken along line C-C of FIG. 10;

FIGS. 12 to 18 are cross-sectional views illustrating a method of manufacturing an image sensor, according to embodiments; and

FIG. 19 is a block diagram illustrating a configuration of an image sensor according to an embodiment.

### DETAILED DESCRIPTION OF THE EMBODIMENTS

Hereinafter, embodiments will be described in detail with reference to the accompanying drawings.

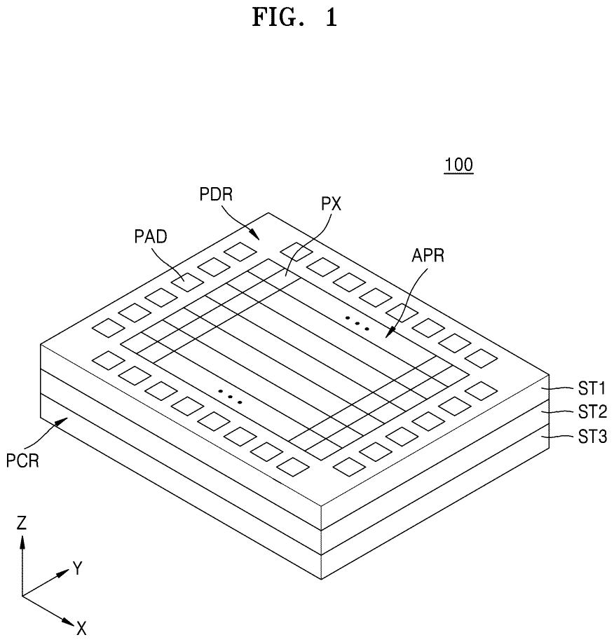

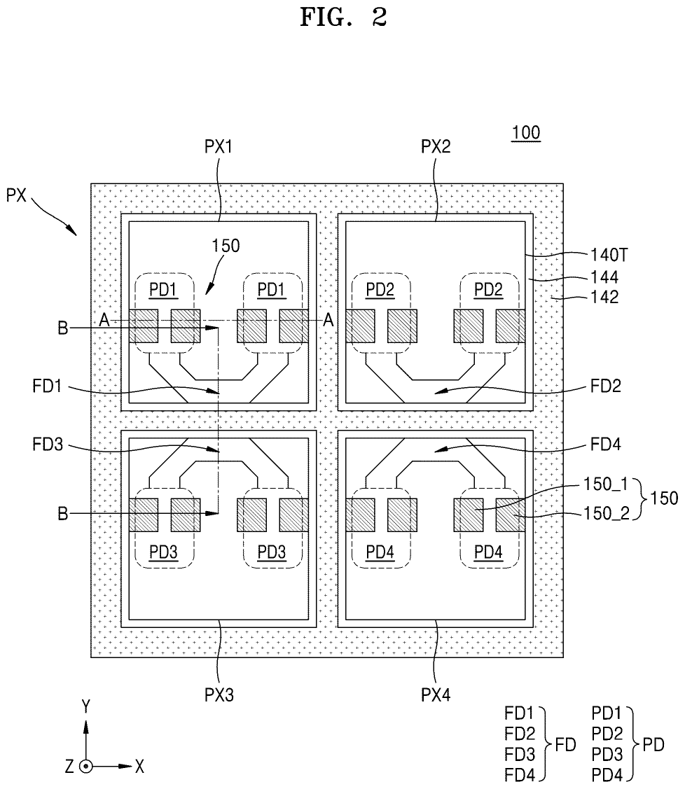

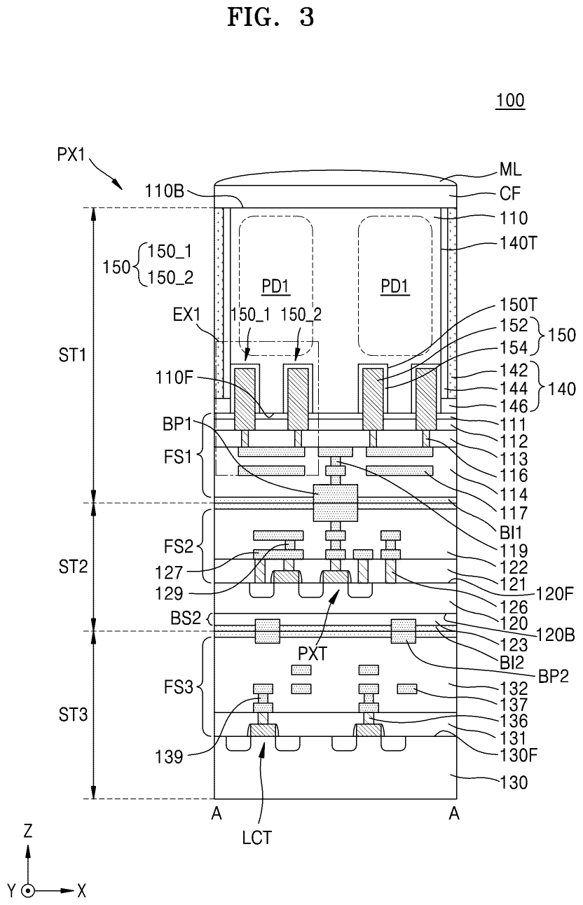

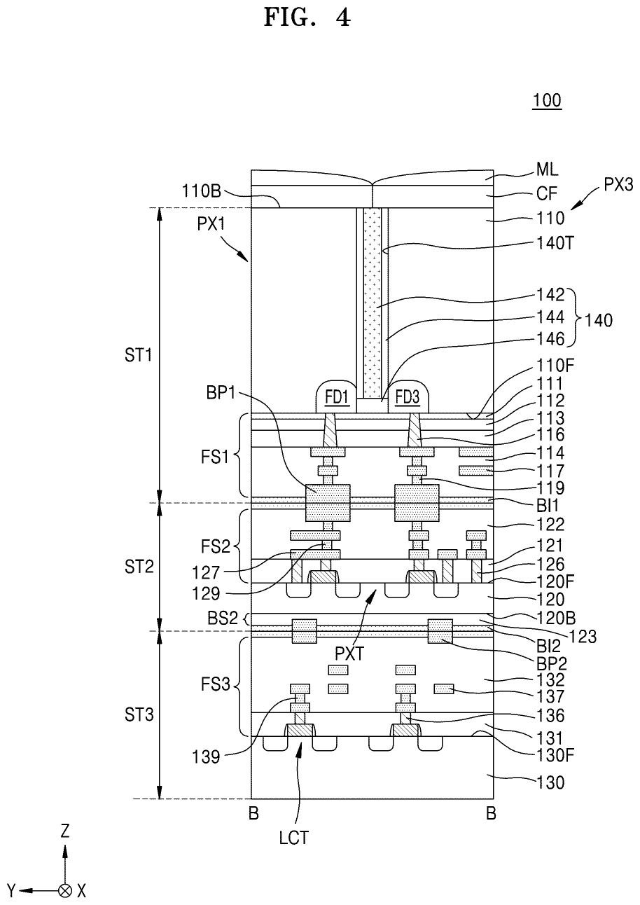

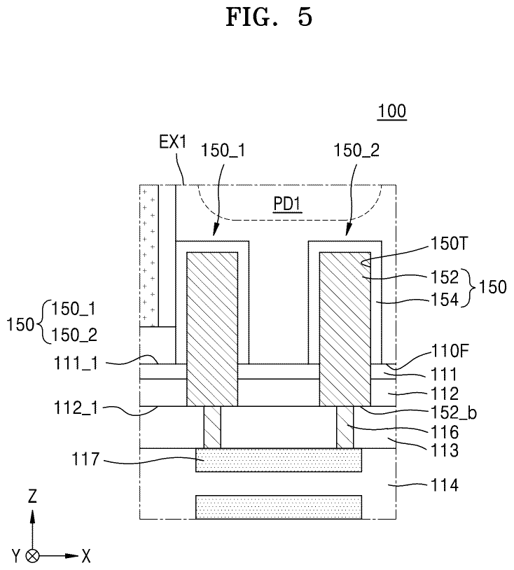

FIG. 1 is a perspective view schematically illustrating an image sensor 100 according to embodiments. FIG. 2 is a layout view illustrating the image sensor 100 corresponding to one pixel PX of FIG. 1. FIG. 3 is a cross-sectional view taken along line A-A of FIG. 2. FIG. 4 is a cross-sectional view taken along line B-B of FIG. 2. FIG. 5 is an enlarged cross-sectional view of a region EX1 of FIG. 3.

Referring to FIGS. 1 to 5, the image sensor 100 may be a stacked image sensor where a first stack ST1, a second stack ST2, and a third stack ST3 are stacked in a vertical direction.

An active pixel region APR may be disposed at the center portion of the image sensor 100, and a plurality of pixels PX may be disposed in the active pixel region APR. Each of the plurality of pixels PX may be a region which receives light from the outside of the image sensor 100 and converts the received light into an electrical signal. The plurality of pixels PX may be disposed in the first stack ST1 and the second stack ST2. A photoelectric conversion region PD for receiving external light may be disposed in the first stack ST1. Transistors configuring a pixel circuit PXC for converting a photocharge, accumulated in the photoelectric conversion region PD, into an electrical signal may be disposed in the second stack ST2. Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first” in a particular claim) may be described elsewhere with a different ordinal number (e.g., “second” in the specification or another claim).

A pad region PDR may be disposed on at least one side of the active pixel region APR, and for example, may be disposed on four side surfaces of the active pixel region APR in a plan view. A plurality of pads PAD may be disposed in the pad region PDR and may be configured to transfer and receive an electrical signal to and from an external device.

The image sensor 100 may also include a peripheral circuit region PCR. The peripheral circuit region PCR may include a logic circuit block and/or a memory device. For example, the logic circuit block may include a plurality of logic transistors LCT and may provide a certain signal to each pixel PX of the active pixel region APR or may control an output signal of each pixel PX. For example, the logic transistor LCT may include at least one of a row decoder, a row driver, a column decoder, a timing generator, a correlated double sampler (CDS), an analog-to-digital converter (ADC), and an input/output (I/O) buffer.

The active pixel region APR may include the plurality of pixels PX, and a plurality of photoelectric conversion regions PD may be respectively disposed in the plurality of pixels PX. In the active pixel region APR, the plurality of pixels PX may be arranged in a matrix form including columns and rows in a first direction X, which is parallel to an upper surface of a first semiconductor substrate 110, and a second direction Y, which is perpendicular to the first direction X and is parallel to the upper surface of the first semiconductor substrate 110. Some of the plurality of pixels PX may be optical black pixels (not shown). The optical black pixel may function as a reference pixel for the active pixel region APR and may perform a function of automatically correcting a dark signal.

In some embodiments, as illustrated in FIG. 2, a first pixel PX1, a second pixel PX2, a third pixel PX3, and a fourth pixel PX4 may be arranged in a matrix form. Each of the first to fourth pixels PX1 to PX4 of the first stack ST1 may include a photoelectric conversion region PD and a floating diffusion region FD.

For example, the first pixel PX1 may include a first photoelectric conversion region PD1 and a first floating diffusion region FD1. The second pixel PX2 may include a second photoelectric conversion region PD2 and a second floating diffusion region FD2. The third pixel PX3 may include a third photoelectric conversion region PD3 and a third floating diffusion region FD3. The fourth pixel PX4 may include a fourth photoelectric conversion region PD4 and a fourth floating diffusion region FD4.

In some embodiments, two photoelectric conversion regions PD may be disposed in one pixel PX. For example, the first pixel PX1 may include two first photoelectric conversion regions PD1. For example, the second pixel PX2 may include two second photoelectric conversion regions PD2. For example, the third pixel PX3 may include two third photoelectric conversion regions PD3. For example, the fourth pixel PX4 may include two fourth photoelectric conversion regions PD4.

The first stack ST1 may include the first semiconductor substrate 110 including a front-side surface 110F and a backside surface 110B, the photoelectric conversion region PD and the floating diffusion region FD each formed in the first semiconductor substrate 110, a dual transfer gate 150 and a first front-side structure FS1 each disposed on the front-side surface 110F of the first semiconductor substrate 110. The first stack STI may also include a color filter CF and a micro-lens ML each disposed on the backside surface 110B of the first semiconductor substrate 110.

The second stack ST2 may include a second semiconductor substrate 120 including a front-side surface 120F and a backside surface 120B. The second stack ST2 may include a pixel transistor PXT and a second front-side structure FS2 each disposed on the front-side surface 120F of the second semiconductor substrate 120. The second stack ST2 may also include a backside structure BS2 disposed on the backside surface 120B of the second semiconductor substrate 120.

The third stack ST3 may include a third semiconductor substrate 130 including a front-side surface 130F. The third stack ST3 may also include a logic transistor LCT and a third front-side structure FS3 each disposed on the front-side surface 130F of the third semiconductor substrate 130.

The second stack ST2 may be disposed between the first stack ST1 and the third stack ST3, and for example, the second front-side structure FS2 of the second stack ST2 may be disposed to face the first front-side structure FS1 of the first stack ST1 and the backside structure BS2 of the second stack ST2 may be disposed to face the third front-side structure FS3 of the third stack ST3.

In some embodiments, the first to third semiconductor substrates 110 to 130 may each include a P-type semiconductor substrate. For example, at least one of the first to third semiconductor substrates 110 to 130 may include a P-type silicon substrate. In some embodiments, at least one of the first to third semiconductor substrates 110 to 130 may include a P-type bulk substrate and a P-type or N-type epitaxial layer grown thereon, and in other embodiments, at least one of the first to third semiconductor substrates 110 to 130 may include an N-type bulk substrate and a P-type or N-type epitaxial layer grown thereon.

A pixel isolation structure 140 may be disposed in the first semiconductor substrate 110 of the first stack ST1. The plurality of pixels PX may be defined by the pixel isolation structure 140. The pixel isolation structure 140 may include a conductive layer 142, an insulation liner 144, and an upper insulation layer 146. The conductive layer 142 may be disposed in a pixel trench 140T passing through the first semiconductor substrate 110. The insulation liner 144 may be disposed on an inner sidewall of the pixel trench 140T passing through the first semiconductor substrate 110 and may be disposed between the conductive layer 142 and the first semiconductor substrate 110 to extend up to a second surface 110F2 of the first semiconductor substrate 110 from the front-side surface 110F of the first semiconductor substrate 110. The upper insulation layer 146 may be disposed in a portion of the pixel trench 140T adjacent to the front-side surface 110F of the first semiconductor substrate 110.

In embodiments, the pixel isolation structure 140 may pass through the first semiconductor substrate 110. For example, the pixel isolation structure 140 may be a front-side deep trench isolation (FDTI). Unlike the illustration, the pixel isolation structure 140 may not pass through the first semiconductor substrate 110. For example, the pixel isolation structure 140 may be a backside deep trench isolation (BDTI).

In some embodiments, the conductive layer 142 may include at least one of doped polysilicon, metal, metal silicide, metal nitride, and a metal-containing layer. The insulation liner 144 may include or may be formed of an insulating material such as silicon oxide, silicon nitride, and silicon oxynitride. The upper insulation liner 146 may include or may be formed of an insulating material such as silicon oxide, silicon nitride, and silicon oxynitride.

As illustrated in FIGS. 2 and 4, the floating diffusion region FD may be disposed in an internal region of the first semiconductor substrate 110 adjacent to the front-side surface 110F of the first semiconductor substrate 110 of the first stack ST1. The floating diffusion region FD may be a region which stores an electric charge transferred from an adjacent photoelectric conversion region PD. In some embodiments, in a case where two photoelectric conversion regions PD are disposed in one pixel PX, the floating diffusion region FD may be shared by the two photoelectric conversion regions PD. For example, in a case where one pixel PX includes two photoelectric conversion regions PD, the floating diffusion region FD may be a region which stores electric charges transferred from two photoelectric conversion regions PD of a corresponding pixel PX.

For example, the first floating diffusion region FD1 of the first pixel PX1 may be shared by two first photoelectric conversion regions PD1. The second floating diffusion region FD2 of the second pixel PX2 may be shared by two second photoelectric conversion regions PD2. The third floating diffusion region FD3 of the third pixel PX3 may be shared by two third photoelectric conversion regions PD3. The fourth floating diffusion region FD4 of the fourth pixel PX4 may be shared by two fourth photoelectric conversion regions PD4.

A ground region (not shown) may be disposed in an internal region of the first semiconductor substrate 110 adjacent to the front-side surface 110F of the first semiconductor substrate 110 of the first stack ST1.

As illustrated in FIGS. 3 and 4, the first front-side structure FS1 may be disposed on the front-side surface 110F of the first semiconductor substrate 110 of the first stack ST1. The first front-side structure FS1 may include a first insulation layer 111 and a second insulation layer 112, which are disposed on the front-side surface 110F of the first semiconductor substrate 110. In some other embodiments, the front-side structure FS1 may include the first insulation layer 111 which is disposed on the front-side surface 110F of the first semiconductor substrate 110. The first insulation layer 111 and the second insulation layer 112 may include or may be formed of at least one of silicon oxide, silicon nitride, silicon oxynitride, and silicon carbon nitride. For example, the first insulation layer 111 may include or may be formed of silicon oxide, and the second insulation layer 112 may include or may be formed of silicon nitride. Furthermore, each of the first and second insulation layers 111 and 112 may be formed in a stack structure of a plurality of insulation layers (not shown), and an additional insulation liner (not shown) may be further disposed between two adjacent insulation layers of the plurality of insulation layers.

The first front-side structure FS1 may include a third insulation layer 113 and a fourth insulation layer 114, which are disposed on the first insulation layer 111 and the second insulation layer 112. The first front-side structure FS1 may further include a plurality of conductive vias 116, passing through the third insulation layer 113, and a wiring layer 117 and a via 119 each disposed in the fourth insulation layer 114. For example, the first front-side structure FS1 may include the plurality of conductive vias 116, the wiring layer 117, and the via 119, which are connected to each of the first floating diffusion region FD1 and the third floating diffusion region FD3.

In some other embodiments, the first floating diffusion region FD1 and the third floating diffusion region FD3 may be electrically connected with each other by the plurality of conductive vias 116, the wiring layer 117, and the via 119, in the third insulation layer 114.

As illustrated in FIGS. 2 and 3, the dual transfer gate 150 may be disposed in the first semiconductor substrate 110 of the first stack ST1. In detail, two dual transfer gates 150 respectively corresponding to two first photoelectric conversion regions PD1 of the first pixel PX1 may be disposed. The dual transfer gate 150 may be adjacent to the front-side surface 110F of the first semiconductor substrate 110. Two dual transfer gates 150 respectively corresponding to two first photoelectric conversion regions PD1 of the first pixel PX1 may share the first floating diffusion region FD1 of the first pixel PX1.

In some embodiments, the dual transfer gate 150 may include a dual transfer gate electrode 152 which passes through the first insulation layer 111 and the second insulation layer 112 and is disposed in a transfer gate trench 150T extending to an inner portion of the first semiconductor substrate 110. The dual transfer gate electrode 152 may include a first sub transfer gate electrode 150_1 and a second sub transfer gate electrode 150_2, which are adjacent to each other in a first horizontal direction (an X direction). The first sub transfer gate electrode 150_1 and the second sub transfer gate electrode 150_2 may include a portion surrounded by the first insulation layer 111 and the second insulation layer 112 and a portion disposed in the first semiconductor substrate 110. For example, the first sub transfer gate electrode 150_1 and the second sub transfer gate electrode 150_2 may include at least a portion which is not buried in the first semiconductor substrate 110.

In some other embodiments, the dual transfer gate electrode 152 may include a first sub transfer gate electrode 150_1 and a second sub transfer gate electrode 150_2, which are adjacent to each other in a second horizontal direction (a Y direction).

In some embodiments, a transfer gate insulation layer 154 may be disposed between the dual transfer gate electrode 152 and the first semiconductor substrate 110 to have a relatively uniform thickness. The transfer gate insulation layer 154 may not be disposed between the dual transfer gate electrode 152 and the first and second insulation layers 111 and 112.

In other embodiments, the transfer gate insulation layer 154 may be disposed on an inner wall of the transfer gate trench 150T. For example, the transfer gate insulation layer 154 may be disposed between the dual transfer gate electrode 152 and the first semiconductor substrate 110 and between the dual transfer gate electrode 152 and the first and second insulation layers 111 and 112.

In detail, referring to FIGS. 2 and 3 in conjunction with FIG. 5, the dual transfer gate 150 may extend to the inner portion of the first semiconductor substrate 110 from a lower surface 112_1 of the second insulation layer 112. A lower surface 152_b of each of the first sub transfer gate electrode 150_1 and the second sub transfer gate electrode 150_2 may be disposed at a vertical level which is equal to the lower surface 112_1 of the second insulation layer 112. The lower surface 152_b of each of the first sub transfer gate electrode 150_1 and the second sub transfer gate electrode 150_2 may be disposed at a vertical level which is lower than an upper surface 111_1 of the first insulation layer 111. An upper surface of each of the first sub transfer gate electrode 150_1 and the second sub transfer gate electrode 150_2 may be disposed at a vertical level which is higher than the upper surface 111_1 of the first insulation layer 111. Herein, being disposed at a high or low vertical level may denote being disposed at a higher or lower vertical level in a +Z direction.

In some embodiments, with respect to a cross-sectional surface, a side surface of each of the first sub transfer gate electrode 150_1 and the second sub transfer gate electrode 150_2 may not have a step height. In detail, the side surface of each of the first sub transfer gate electrode 150_1 and the second sub transfer gate electrode 150_2 may not have a step height at a boundary between the first semiconductor substrate 110 and the first insulation layer 111. In detail, the side surface of each of the first sub transfer gate electrode 150_1 and the second sub transfer gate electrode 150_2 may not have a step height in the first insulation layer 111. For example, a width of each of the first sub transfer gate electrode 150_1 and the second sub transfer gate electrode 150_2 in the first horizontal direction (the X direction) may be constant or continuously change. For example, a width of each of the first sub transfer gate electrode 150_1 and the second sub transfer gate electrode 150_2 in the first horizontal direction (the X direction) may not include a portion which discontinuously changes.

In some embodiments, the first sub transfer gate electrode 150_1 and the second sub transfer gate electrode 150_2 may not be connected with each other in the first semiconductor substrate 110. The first sub transfer gate electrode 150_1 and the second sub transfer gate electrode 150_2 may not be connected with each other in the first insulation layer 111 and the second insulation layer 112.

In some embodiments, each of the plurality of conductive vias 116 disposed in the third insulation layer 113 may be connected to the first sub transfer gate electrode 150_1 and the second sub transfer gate electrode 150_2. The wiring layer 117 disposed in the fourth insulation layer 114 may be connected to the plurality of conductive vias 116 connected to each of the first sub transfer gate electrode 150_1 and the second sub transfer gate electrode 150_2 in common.

In some embodiments, the dual transfer gate electrode 152 may have an etch selectivity corresponding to each of the first insulation layer 111 and the second insulation layer 112. For example, the dual transfer gate electrode 152 may include a material having an etch selectivity corresponding to silicon oxide, silicon nitride, silicon oxynitride, or silicon carbon nitride. For example, the dual transfer gate electrode 152 may include polysilicon.

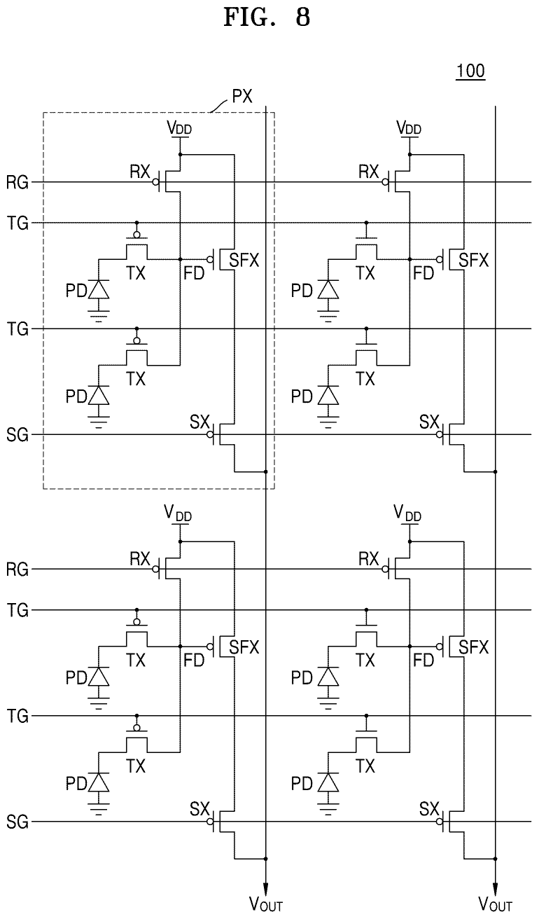

Referring again to FIGS. 3 and 4, the second front-side structure FS2 may be disposed on the front-side surface 120F of the second semiconductor substrate 120 of the second stack ST2. The second front-side structure FS2 may include a first insulation layer 121 and a second insulation layer 122, which are disposed on the front-side surface 120F of the second semiconductor substrate 120. The first insulation layer 121 may cover the pixel transistor PXT disposed on the front-side surface 120F of the second semiconductor substrate 120. The second front-side structure FS2 may further include a conductive via 126, passing through the first insulation layer 121, and a wiring layer 127 and a via 129 each disposed in the second insulation layer 122. The conductive via 126, the wiring layer 127, and the via 129 may be disposed to be electrically connected to the pixel transistor PXT. In some embodiments, the pixel transistor PXT may include a reset transistor RX, a selection transistor SX, and a source follower transistor SFX (see FIG. 8).

The backside structure BS2 may be disposed on the backside surface 120B of the second semiconductor substrate 120 of the second stack ST2. The backside structure BS2 may include a third insulation layer 123 which is disposed on the backside surface 120B of the second semiconductor substrate 120.

The third front-side structure FS3 may be disposed on the front-side surface 130F of the third semiconductor substrate 130 of the third stack ST3. The third front-side structure FS3 may include a first insulation layer 131 and a second insulation layer 132, which are disposed on the front-side surface 130F of the third semiconductor substrate 130. The first insulation layer 131 may cover the logic transistor LCT disposed on the front-side surface 130F of the third semiconductor substrate 130. The third front-side structure FS3 may further include a conductive via 136, passing through the first insulation layer 131, and a wiring layer 137 and a via 139 each disposed in the second insulation layer 132. The conductive via 136, the wiring layer 137, and the via 139 may be disposed to be electrically connected to the logic transistor LCT.

In some embodiments, the conductive vias 116, 126, and 136, the wiring layers 117, 127, and 137, and the vias 119, 129, and 139 may include at least one of copper (Cu), aluminum (Al), tungsten (W), titanium (Ti), titanium nitride (TiN), tantalum (Ta), tantalum nitride (TaN), ruthenium (Ru), and tungsten nitride (WN).

As illustrated in FIGS. 3 and 4, the second front-side structure FS2 of the second stack ST2 may be disposed to face the first front-side structure FS1 of the first stack ST1. A first bonding layer BI1 may be disposed between the first front-side structure FS1 and the second front-side structure FS2. The backside structure BS2 of the second stack ST2 may be disposed to face the third front-side structure FS3 of the third stack ST3. A second bonding layer BI2 may be disposed between the backside structure BS1 and the third front-side structure FS3. Each of the first bonding layer BI1 and the second bonding layer BI2 may be formed in a stack structure of a plurality of insulation layers and for example, may include or may be formed of at least one of silicon oxide, silicon nitride, silicon oxynitride, or silicon carbon nitride.

In some embodiments, a first bonding pad BP1 may be disposed at a boundary between the first stack ST1 and the second stack ST2. The first bonding pad BP1 may be surrounded by the first bonding layer BI1. The first bonding pad BP1 may include an upper pad part of the first stack ST1 and a lower pad part of the second stack ST2, and the upper pad part and the lower pad part may be disposed to overlap and be attached on each other. For example, an interface (for example, a bonding interface) between the upper pad part and the lower pad part may be disposed between the first front-side structure FS1 and the second front-side structure FS2. The first bonding pad BP1 may include copper. For example, the first stack ST1 and the second stack ST2 may be stacked by a metal-oxide hybrid bonding process.

In some embodiments, as illustrated in FIG. 4, two first bonding pads BP1 connected to each of the first floating diffusion region FD1 and the third floating diffusion region FD3 may be disposed. In other embodiments, when the first floating diffusion region FD1 and the third floating diffusion region FD3 are electrically connected with each other in the third insulation layer 114 by using the plurality of conductive vias 116, the wiring layer 117, and/or the via 119, one first bonding pad BP1 connected to the first floating diffusion region FD1 and the third floating diffusion region FD3 may be disposed.

In some embodiments, a second bonding pad BP2 may be disposed at a boundary between the second stack ST2 and the third stack ST3. The second bonding pad BP2 may be surrounded by the second bonding layer BI2. The second stack ST2 and the third stack ST3 may be stacked by a metal-oxide hybrid bonding process. The second bonding pad BP2 may include copper.

According to some embodiments, the image sensor 100 including the dual transfer gate 150 including the first sub transfer gate electrode 150_1 and the second sub transfer gate electrode 150_2 may be provided. Because the first sub transfer gate electrode 150_1 and the second sub transfer gate electrode 150_2 are not connected with each other in the first insulation layer 111 and the second insulation layer 112, capacitance may decrease, and thus, photoelectric conversion efficiency such as a conversion gain and noise of the image sensor 100 may be improved. Also, the conductive via 116 connected to the first sub transfer gate electrode 150_1 and the second sub transfer gate electrode 150_2 may be formed in the third insulation layer 113, and thus, the image sensor 100 having a reduced vertical height may be provided. That is, the image sensor 100 having enhanced performance and reliability may be provided.

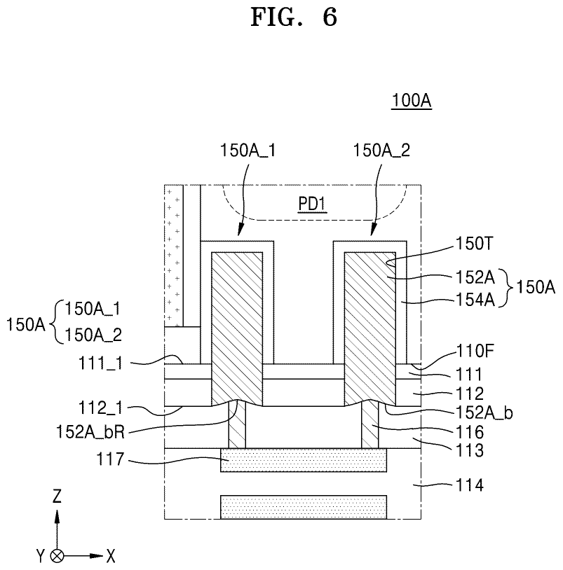

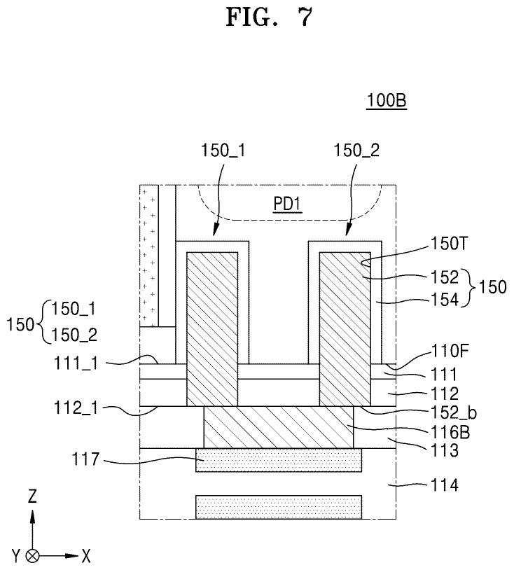

FIGS. 6 and 7 are enlarged cross-sectional views of image sensors 100A and 100B according to some embodiments. Hereinafter, the difference with the image sensor 100 described above with reference to FIGS. 1 to 5 is mainly described.

Referring to FIG. 6, the image sensor 100A may include a dual transfer gate 150A. The dual transfer gate 150A may include a dual transfer gate electrode 152A which passes through a first insulation layer 111 and a second insulation layer 112 and is buried in a first semiconductor substrate 110. The dual transfer gate electrode 152A may include a first sub transfer gate electrode 150A_1 and a second sub transfer gate electrode 150A_2, which are adjacent to each other in a first horizontal direction (an X direction).

A lower surface 152A_b of the dual transfer gate electrode 152A may be disposed at a vertical level which is higher than or equal to a lower surface 112_1 of the second insulation layer 112. In detail, a lower surface of each of the first sub transfer gate electrode 150A_1 and the second sub transfer gate electrode 150A_2 may be disposed at a vertical level which is higher than or equal to the lower surface 112_1 of the second insulation layer 112. For example, the uppermost portion of the lower surface of each of the first sub transfer gate electrode 150A_1 and the second sub transfer gate electrode 150A_2 may be disposed at a vertical level which is higher than or equal to the lower surface 112_1 of the second insulation layer 112.

The lower surface 152A_b of the dual transfer gate electrode 152A may be disposed at a vertical level which is lower than an upper surface 111_1 of the first insulation layer 111. In detail, the lower surface of each of the first sub transfer gate electrode 150A_1 and the second sub transfer gate electrode 150A_2 may be disposed at a vertical level which is lower than the upper surface 111_1 of the first insulation layer 111. An upper surface of each of the first sub transfer gate electrode 150A_1 and the second sub transfer gate electrode 150A_2 may be disposed at a vertical level which is higher than the upper surface 111_1 of the first insulation layer 111.

As illustrated in FIG. 6, the lower surface 152A_b of the dual transfer gate electrode 152A may include a recess portion 152A_bR. In detail, a lower surface of each of the first sub transfer gate electrode 150A_1 and the second sub transfer gate electrode 150A_2 may include a recess portion. In detail, the recess portion 152A_bR of the dual transfer gate electrode 152A may be recessed to an inner portion of the dual transfer gate electrode 152A. For example, the recess portion 152A_bR of the dual transfer gate electrode 152A may be recessed toward an upper surface of the dual transfer gate electrode 152A.

Referring to FIG. 7, the image sensor 100B may include a dual transfer gate 150. The dual transfer gate 150 may include a first sub transfer gate electrode 150_1 and a second sub transfer gate electrode 150_2, which pass through a first insulation layer 111 and a second insulation layer 112 and are buried in a first semiconductor substrate 110.

In embodiments, a conductive via 116B disposed in a third insulation layer 113 may be connected to the first sub transfer gate electrode 150_1 and the second sub transfer gate electrode 150_2 in common. A wiring layer 117 disposed in a fourth insulation layer 114 may be connected to the conductive via 116B connected to the first sub transfer gate electrode 150_1 and the second sub transfer gate electrode 150_2 in common.

FIG. 8 is an equivalent circuit diagram of an image sensor 100 according to embodiments.

Referring to FIG. 8, a plurality of pixels PXT may be arranged in a matrix form. Each of the plurality of pixels PXT may include a transfer transistor TX and pixel transistors (not shown). Here, the pixel transistors may include a reset transistor RX, a selection transistor SX, and a source follower transistor SFX. The reset transistor RX may include a reset gate RG, the selection transistor SX may include a selection gate SG, the source follower transistor SFX may include a source follower gate (not shown), and the transfer transistor TX may include a transfer gate TG. The transfer gate TG may correspond to the dual transfer gate 150 described above with reference to FIGS. 1 to 5.

Each of the plurality of pixels PX may further include a photoelectric diffusion region PD and a floating diffusion region FD. The photoelectric diffusion region PD may correspond to the photoelectric diffusion region PD described above with reference to FIGS. 1 to 5. The photoelectric diffusion region PD may generate and accumulate photocharges in proportion to the amount of light incident from the outside and may use a photodiode, a photo transistor, a photo gate, a pinned photodiode (PPD), and a combination thereof.

In some embodiments, each of the plurality of pixels PX may include two photoelectric diffusion regions PD, two transfer transistors TX, and one floating diffusion regions FD.

The transfer gate TG may transfer an electric charge, generated in the photoelectric diffusion region PD, to the floating diffusion region FD. For example, each of two transfer gates TG of one pixel PX may transfer an electric charge, generated in each of two photoelectric diffusion regions PD, to the floating diffusion region FD. The floating diffusion region FD may accumulate and store electric charges which are generated and transferred by the photoelectric diffusion region PD. The source follower transistor SFX may be controlled based on the amount of photocharges accumulated in the floating diffusion region FD.

The reset transistor RX may periodically reset electric charges accumulated in the floating diffusion region FD. A drain electrode of the reset transistor RX may be connected to the floating diffusion region FD, and a source electrode may be connected to a source voltage VDD. When the reset transistor RX is turned on, the source voltage VDD connected to the source electrode of the reset transistor RX may be transferred to the floating diffusion region FD. When the reset transistor RX is turned on, electric charges accumulated in the floating diffusion region FD may be discharged and thus, the floating diffusion region FD may be reset.

The source follower transistor SFX may be connected to a current source (not shown) disposed outside the plurality of pixels PX to function as a source follower buffer amplifier and may provide an electric potential variation in the floating diffusion region FD to output an amplified voltage to an output line V_{OUT}.

The selection transistor SX may select a plurality of pixels PX by row units, and when the selection transistor SX is turned on, the source voltage VDD may be transferred to a source electrode of the source follower transistor SFX.

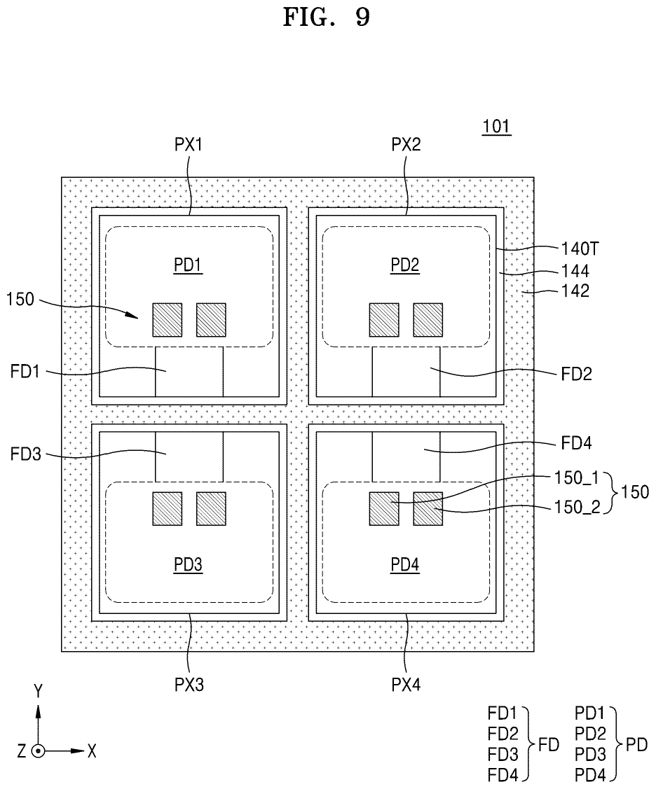

FIG. 9 is a layout view illustrating an image sensor 101 according to some embodiments. Hereinafter, the difference with the image sensor 100 described above with reference to FIGS. 1 to 5 is mainly described.

Referring to FIG. 9, the image sensor 101 may include a first pixel PX1, a second pixel PX2, a third pixel PX3, and a fourth pixel PX4. Unlike the image sensor 100 described above with reference to FIGS. 1 to 5, each of the first pixel PX1, the second pixel PX2, the third pixel PX3, and the fourth pixel PX4 of the image sensor 101 may include one photoelectric conversion region PD and one floating diffusion region FD.

Each of the first pixel PX1, the second pixel PX2, the third pixel PX3, and the fourth pixel PX4 may include a dual transfer gate 150. The dual transfer gate 150 may include a first sub transfer gate electrode 150_1 and a second sub transfer gate electrode 150_2.

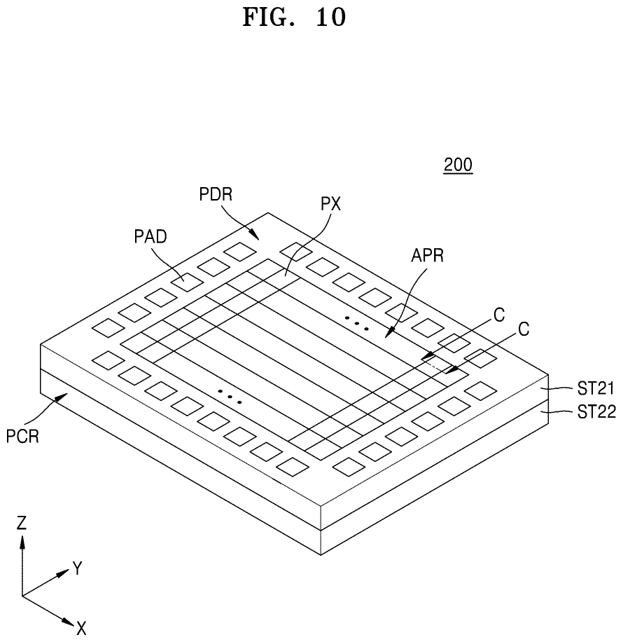

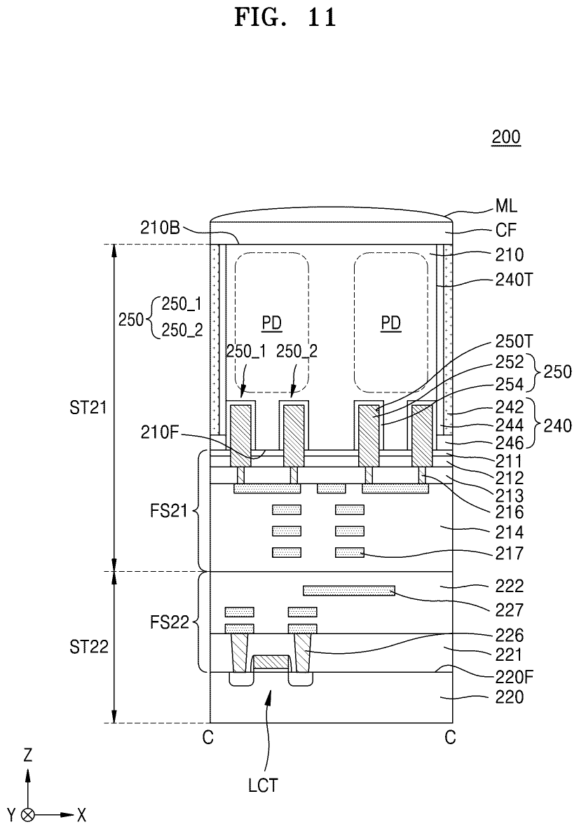

FIG. 10 is a perspective view schematically illustrating an image sensor 200 according to some embodiments. FIG. 11 is a cross-sectional view taken along line C-C of FIG. 10. Hereinafter, the difference with the image sensor 100 described above with reference to FIGS. 1 to 5 is mainly described.

Referring to FIGS. 10 and 11, the image sensor 200 may be a stacked image sensor where a first stack ST21 and a second stack ST22 are stacked in a vertical direction.

In embodiments, a plurality of pixels PX, a photoelectric conversion region PD, and a plurality of pixel transistors may be disposed in the first stack ST21. A peripheral circuit region PCR may be disposed in the second stack ST22 and may include a logic circuit block and/or a memory device. For example, the logic circuit block may include a plurality of logic transistors LCT.

The first stack ST21 may include a first semiconductor substrate 210, a first front-side structure FS21 disposed on a first surface 210F of the first semiconductor substrate 210, and a color filter CF and a micro-lens ML each disposed on a second surface 210B of the first semiconductor substrate 210. The second stack ST22 may include a second semiconductor substrate 220 and a second front-side structure FS22 disposed on a first surface 220F of the second semiconductor substrate 220.

For example, the second front-side structure FS22 of the second stack ST22 may be disposed to face and contact the first front-side structure FS21 of the first stack ST21.

In embodiments, the first front-side structure FS21 may include a first insulation layer 211 and a second insulation layer 212, which are disposed on a front-side surface 110F of the first semiconductor substrate 110.

The first front-side structure FS21 may include a third insulation layer 213 and a fourth insulation layer 214, which are disposed on the first insulation layer 211 and the second insulation layer 212. The first front-side structure FS21 may further include a wiring layer 217 which is disposed in the fourth insulation layer 214.

The second front-side structure FS22 may include a first insulation layer 221 and a second insulation layer 222, which are disposed on the first surface 220F of the second semiconductor substrate 220. The first insulation layer 221 may cover the logic transistor LCT disposed on the first surface 220F of the second semiconductor substrate 220. The second front-side structure FS22 may further include a conductive via 226, passing through the first insulation layer 221, and a wiring layer 227 disposed in the second insulation layer 222. The conductive via 226 and the wiring layer 227 may be disposed to be electrically connected to the logic transistor LCT.

In the first stack ST21 and the second stack ST22, the first front-side structure FS21 and the second front-side structure FS22 may be disposed to face each other, and for example, the fourth insulation layer 412 of the first front-side structure FS21 may be disposed to contact the second insulation layer 222 of the second front-side structure FS22.

A pixel isolation structure 240 may be disposed in the first semiconductor substrate 210 of the first stack ST21. The plurality of pixels PX may be defined by the pixel isolation structure 240. The pixel isolation structure 240 may include a conductive layer 242, an insulation liner 244, and an upper insulation layer 246.

A plurality of photoelectric conversion regions (not shown) may be respectively disposed in first stack ST21 in the plurality of pixels PX. For example, one or more photoelectric conversion regions may be disposed in each pixel PX.

A dual transfer gate 250 may be disposed in the first semiconductor substrate 210 of the first stack ST21. In detail, two dual transfer gates 250 respectively corresponding to two photoelectric conversion regions PD of one pixel PX may be disposed. The dual transfer gate 150 may be adjacent to the front-side surface 210F of the first semiconductor substrate 210.

In some embodiments, the dual transfer gate 250 may include a dual transfer gate electrode 252, which passes through the first insulation layer 211 and the second insulation layer 212 and is disposed in a transfer gate trench 250T extending to an inner portion of the first semiconductor substrate 210. The dual transfer gate electrode 252 may include a first sub transfer gate electrode 250_1 and a second sub transfer gate electrode 250_2, which are adjacent to each other in a first horizontal direction (an X direction). The first sub transfer gate electrode 250_1 and the second sub transfer gate electrode 250_2 may include a portion surrounded by the first insulation layer 211 and the second insulation layer 212 and a portion disposed in the first semiconductor substrate 210. For example, the first sub transfer gate electrode 250_1 and the second sub transfer gate electrode 250_2 may include at least a portion which is not buried in the first semiconductor substrate 210.

In some embodiments, a transfer gate insulation layer 254 may be disposed on an inner wall of the transfer gate trench 250T. The transfer gate insulation layer 254 may be disposed between the dual transfer gate electrode 252 and the first semiconductor substrate 210 to have a relatively uniform thickness.

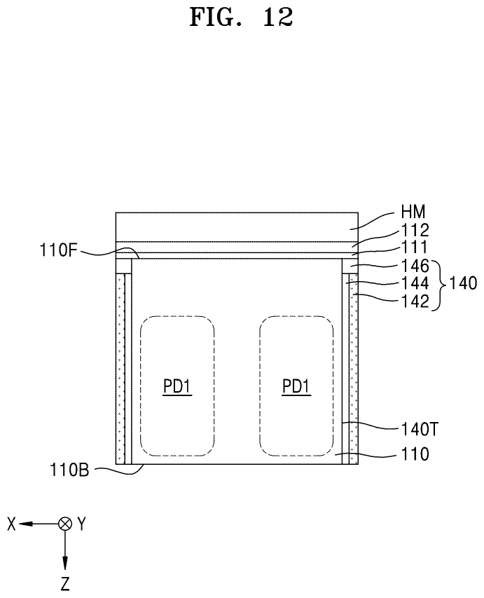

FIGS. 12 to 18 are cross-sectional views illustrating a method of manufacturing an image sensor 100, according to some embodiments. In detail, FIGS. 12 to 18 are cross-sectional views corresponding to a cross-sectional surface taken along line A-A of FIG. 2.

Referring to FIG. 12, a pixel isolation structure 140 and a plurality of photoelectric conversion regions PD1 may be formed in a first semiconductor substrate 110 of a first pixel PX1 (see FIGS. 1 to 4). Subsequently, a first insulation layer 111 and/or a second insulation layer 112 may be formed on a front-side surface 110F of the first semiconductor substrate 110. The first insulation layer 111 and/or the second insulation layer 112 may be formed on the front-side surface 110F of the first semiconductor substrate 110 when the front-side surface 110F of the first semiconductor substrate 110 is provided upwards.

Subsequently, a hard mask layer HM may be formed on the first insulation layer 111 and the second insulation layer 112. In some embodiments, the hard mask layer HM may be a layer which has been used in a previous process. For example, the hard mask layer HM may be reused instead of being newly formed after a previous process is performed.

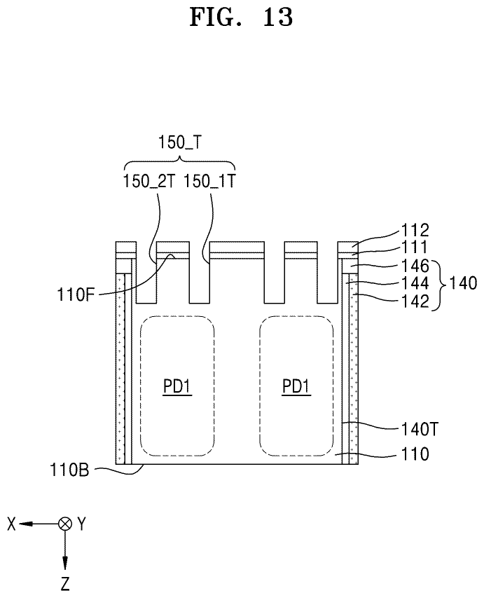

Referring to FIG. 13, a photo mask layer (not shown) may be formed on the hard mask layer HM, and a transfer gate trench 150T may be formed by patterning the hard mask layer HM, the first insulation layer 111, the second insulation layer 112, and a portion of the first semiconductor substrate 110. The transfer gate trench 150T may be formed by etching the hard mask layer HM, the first insulation layer 111, the second insulation layer 112, and a portion of the first semiconductor substrate 110. The transfer gate trench 150T may include a first sub transfer gate trench 150_1T and a second sub transfer gate trench 150_2T, which are adjacent to each other in a first horizontal direction (an X direction). Subsequently, the hard mask layer HM may be removed.

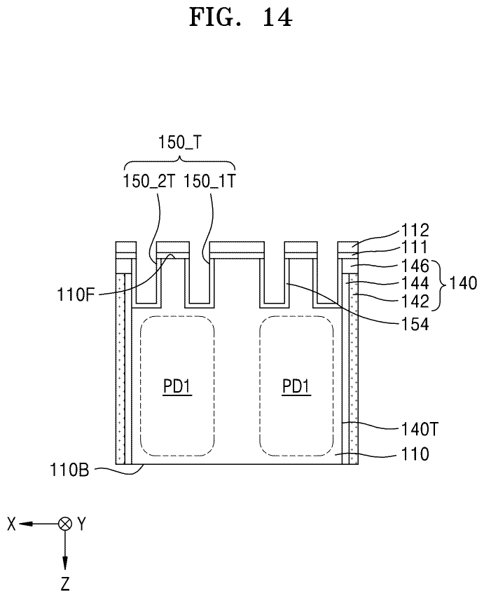

Referring to FIG. 14, a transfer gate insulation layer 154 may be formed. In detail, the transfer gate insulation layer 154 may be formed by performing an oxidation process on the first semiconductor substrate 110 exposed by an inner wall of the transfer gate trench 150T. In the oxidation process, the first insulation layer 111 and the second insulation layer 112 each exposed by the transfer gate trench 150T may not be oxidized or may be hardly (e.g., partially) oxidized, and thus, the transfer gate insulation layer 154 may not be formed on the first insulation layer 111 and the second insulation layer 112.

In other embodiments, the transfer gate insulation layer 154 may be formed by coating an insulation layer on an inner wall of the transfer gate trench 150T. For example, the transfer gate insulation layer 154 may be formed by coating an insulation layer on the first semiconductor substrate 110, the first insulation layer 111, and the second insulation layer 112 each exposed by an inner wall of the transfer gate trench 150T.

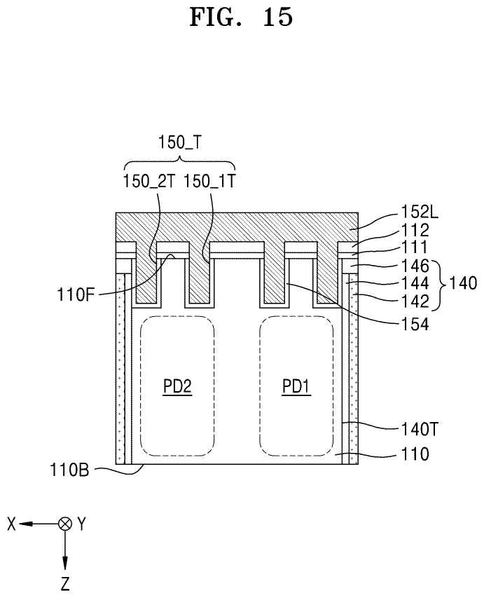

Referring to FIG. 15, a transfer gate electrode layer 152L may be formed in the transfer gate trench 150T and on the first insulation layer 111 and the second insulation layer 112.

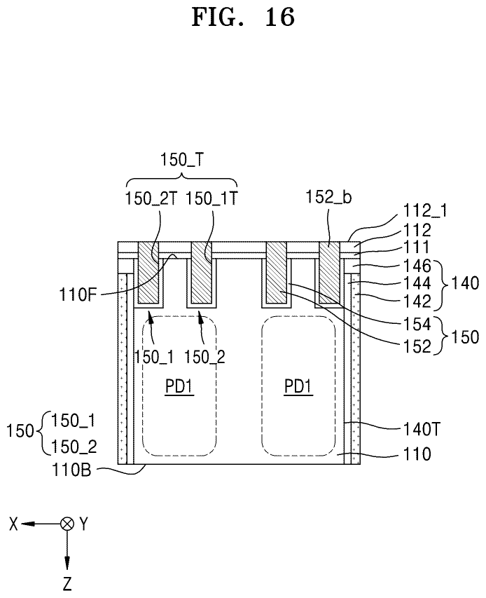

Referring to FIG. 16, a dual transfer gate electrode 152 may be formed by removing a portion of the transfer gate electrode layer 152L formed on the first insulation layer 111 and the second insulation layer 112. In detail, a process of removing a portion of the transfer gate electrode layer 152L may be performed by using a chemical mechanical polishing (CMP) process. A process of performing the CMP process may include a process of stopping the CMP process when the first insulation layer 111 and the second insulation layer 112 are exposed in the middle of removing the transfer gate electrode layer 152L. Accordingly, a lower surface 152_b of the dual transfer gate electrode 152 may be disposed at a vertical level which is equal to a lower surface 112_1 of the second insulation layer 112. Based on the process, a dual transfer gate 150 including a first sub transfer gate electrode 150_1 and a second sub transfer gate electrode 150_2 may be formed.

In some other embodiments, a process of removing a portion of the transfer gate electrode layer 152L may be performed by using an etch-back process.

In other embodiments, when the transfer gate electrode layer 152L is etched more than the first insulation layer 111 and the second insulation layer 112, the lower surface 152_b of the dual transfer gate electrode 152 may include a portion disposed at a vertical level (i.e., a vertical level which is higher in a +Z direction) which is higher than the lower surface 112_1 of the second insulation layer 112.

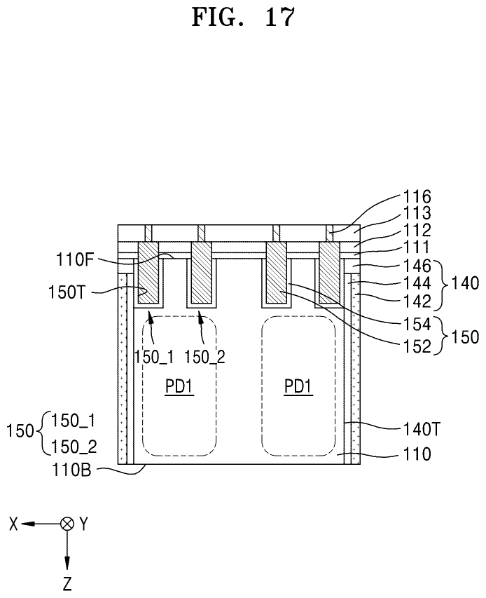

Referring to FIG. 17, a third insulation layer 113 may be formed on the dual transfer gate electrode 152 and the second insulation layer 112, and a plurality of conductive vias 116 may pass through the third insulation layer 113 and may contact the dual transfer gate electrode 152. It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting,” “in contact with,” or “contact” another element, there are no intervening elements present at the point of contact.

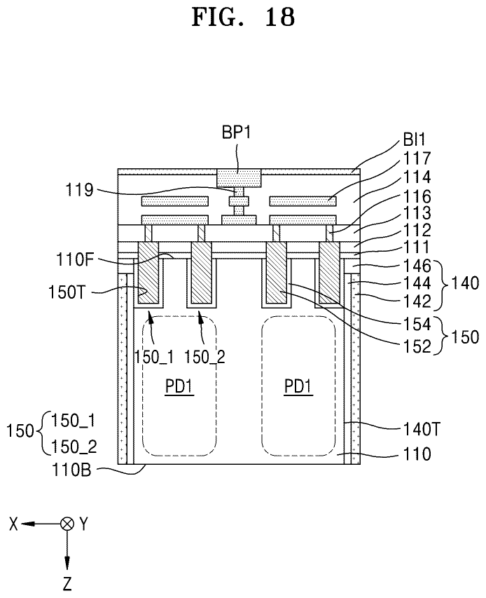

Referring to FIG. 18, a wiring layer 117, a via 119, and a fourth insulation layer 114 surrounding the wiring layer 117 and the via 119 may be formed on the plurality of conductive vias 116 and the third insulation layer 113. Subsequently, a first bonding layer BI1 and a first bonding pad BP1 may be formed.

Subsequently, the image sensor 100 described above with reference to FIGS. 1 to 5 may be formed by performing a post process.

Based on the method of manufacturing the image sensor 100 described above with reference to FIGS. 12 to 18, the dual transfer gate 150 according to an embodiment may be manufactured by using the hard mask layer HM which has been used in a previous process. Accordingly, the image sensor 100 where a manufacturing process is simplified may be provided.

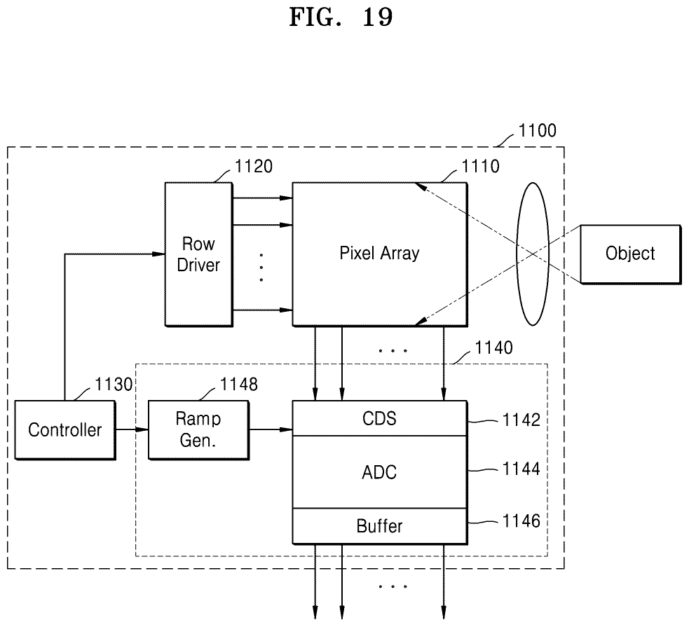

FIG. 19 is a block diagram illustrating a configuration of an image sensor 1100 according to an embodiment.

Referring to FIG. 19, the image sensor 1100 may include a pixel array 1110, a controller 1130, a row driver 1120, and a pixel signal processor 1140. The image sensor 1100 may include at least one of the image sensors 100, 101, 102, 103, and 200 described above with reference to FIGS. 1 to 11.

The pixel array 1110 may include a plurality of unit pixels which are two-dimensionally arranged, and each unit pixel may include a photoelectric conversion element. The photoelectric conversion element may absorb light to generate an electric charge, and an electrical signal (an output voltage) based on the generated electric charge may be provided to the pixel signal processor 1140 through a vertical signal line. Unit pixels included in the pixel array 1110 may provide one output voltage at a time by row units, and thus, unit pixels of one row of the pixel array 1110 may be simultaneously activated by a selection signal output from the row driver 1120. Unit pixels of a selected row may output an output voltage based on absorbed light to an output line of a corresponding column.

The controller 1130 may allow the pixel array 1110 to absorb light and accumulate electric charge, or may control the row driver 1120 to temporarily store accumulated electric charge and output an electrical signal based on a stored electric charge to the outside of the pixel array 1110. Also, the controller 1130 may control the pixel signal processor 1140 to measure an output voltage provided by the pixel array 1110.

The pixel signal processor 1140 may include a correlated double sampling (CDS) circuit 1142, an analog-to-digital conversion (ADC) circuit 1144, and a buffer 1146. The CDS 1142 may sample and hold an output voltage provided by the pixel array 1110. The CDS 1142 may doubly sample a certain noise level and a level based on a generated output voltage to output a level corresponding to the difference therebetween. Also, the CDS 1142 may receive a ramp signal generated by a ramp signal generator 1148 and may compare ramp signals to output a comparison result.

The ADC 1144 may convert an analog signal, corresponding to a level received from the CDS 1142, into a digital signal. The buffer 1146 may latch the digital signal, and the latched digital signal may be sequentially output to the outside of the image sensor 1100 and may be transferred to an image processor (not shown).

Hereinabove, embodiments have been described in the drawings and the specification. Embodiments have been described by using the terms described herein, but this has been merely used for describing aspects of the inventive concept and has not been used for limiting a meaning or limiting the scope of the inventive concept defined in the following claims. Therefore, it may be understood by those of ordinary skill in the art that various modifications and other equivalent embodiments may be implemented from the inventive concept. Accordingly, the spirit and scope of the inventive concept may be defined based on the spirit and scope of the following claims.

While aspects of the inventive concept have been particularly shown and described with reference to embodiments thereof, it will be understood that various changes in form and details may be made therein without departing from the spirit and scope of the following claims.

What is claimed is:

1. An image sensor comprising:
a substrate including a front-side surface and a backside surface opposite thereto;
a unit pixel region disposed in the substrate, the unit pixel region including a photoelectric conversion region;
a pixel isolation structure defining the unit pixel region, extending in a vertical direction in the substrate, and extending in a first horizontal direction and a second horizontal direction;
a first insulation layer disposed on the front-side surface of the substrate; and
a dual transfer gate electrode including a first sub transfer gate electrode and a second sub transfer gate electrode adjacent to each other in the first horizontal direction, each passing through the first insulation layer and accordingly buried in the substrate in the unit pixel region,
wherein a lower surface of each of the first sub transfer gate electrode and the second sub transfer gate electrode is disposed at a vertical level which is lower than an upper surface of the first insulation layer, and
the lower surface of each of the first sub transfer gate electrode and the second sub transfer gate electrode is disposed at a vertical level which is higher than or equal to a lower surface of the first insulation layer.

2. The image sensor of claim 1, wherein the first sub transfer gate electrode and the second sub transfer gate electrode are not connected with each other in the first insulation layer.

3. The image sensor of claim 1, further comprising:
a second insulation layer disposed on the first insulation layer; and
a first conductive via and a second conductive via passing through the second insulation layer and connected to the first sub transfer gate electrode and the second sub transfer gate electrode, respectively.

4. The image sensor of claim 3, further comprising:
a third insulation layer disposed on the second insulation layer; and
a wiring layer connected to the first conductive via and the second conductive via in common, in the third insulation layer.

5. The image sensor of claim 1, further comprising:
a second insulation layer disposed on the first insulation layer; and
a conductive via passing through the second insulation layer and contacting the first sub transfer gate electrode and the second sub transfer gate electrode in common.

6. The image sensor of claim 1, wherein the dual transfer gate electrode comprises a material having an etch selectivity with the first insulation layer.

7. The image sensor of claim 6, wherein the dual transfer gate electrode comprises polysilicon.

8. The image sensor of claim 1, wherein the lower surface of each of the first sub transfer gate electrode and the second sub transfer gate electrode comprises a portion recessed to an inner portion of each of the first sub transfer gate electrode and the second sub transfer gate electrode.

9. The image sensor of claim 1, further comprising a gate insulation layer disposed between the substrate and a portion of the dual transfer gate electrode buried in the substrate.

10. The image sensor of claim 1, further comprising a color filter and a lens each disposed on the backside surface of the substrate.

11. An image sensor comprising:
a substrate including a front-side surface and a backside surface opposite thereto;
a unit pixel region disposed in the substrate, the unit pixel region including a first sub photoelectric conversion region and a second sub photoelectric conversion region;
a pixel isolation structure defining the unit pixel region, extending in a vertical direction in the substrate, and extending in a first horizontal direction and a second horizontal direction;
an insulation layer disposed on the front-side surface of the substrate;
a first dual transfer gate electrode disposed in the substrate to pass through the insulation layer and correspond to the first sub photoelectric conversion region in the unit pixel region; and
a second dual transfer gate electrode disposed in the substrate to pass through the insulation layer and correspond to the second sub photoelectric conversion region in the unit pixel region, wherein
the first dual transfer gate electrode comprises a first sub transfer gate electrode and a second sub transfer gate electrode adjacent thereto in the substrate,
the second dual transfer gate electrode comprises a third sub transfer gate electrode and a fourth sub transfer gate electrode adjacent thereto, in the substrate,
each of the first sub transfer gate electrode, the second sub transfer gate electrode, the third sub transfer gate electrode, and the fourth sub transfer gate electrode comprises at least a portion which is not buried in the substrate, and
a lower surface of each of the first sub transfer gate electrode, the second sub transfer gate electrode, the third sub transfer gate electrode, and the fourth sub transfer gate electrode is disposed at a vertical level which is higher than or equal to a lower surface of the insulation layer.

12. The image sensor of claim 11, wherein the first sub transfer gate electrode and the second sub transfer gate electrode are not connected with each other in the insulation layer.

13. The image sensor of claim 11, further comprising a floating diffusion region shared by the first sub photoelectric conversion region and the second sub photoelectric conversion region in the unit pixel region, and
the floating diffusion region is shared by the first dual transfer gate electrode and the second dual transfer gate electrode.

14. The image sensor of claim 11, wherein the first dual transfer gate electrode and the second dual transfer gate electrode comprise a material having an etch selectivity with the insulation layer.

15. The image sensor of claim 14, wherein the first dual transfer gate electrode and the second dual transfer gate electrode comprise polysilicon.

16. The image sensor of claim 14, wherein the insulation layer comprises silicon nitride.

17. The image sensor of claim 11, wherein in a cross-sectional perspective, a side surface of each of the first sub transfer gate electrode, the second sub transfer gate electrode, the third sub transfer gate electrode, and the fourth sub transfer gate electrode does not have a step height in the insulation layer and a boundary between the substrate and the insulation layer.

18. An image sensor comprising:
a substrate including a front-side surface and a backside surface opposite thereto;
a unit pixel region disposed in the substrate, the unit pixel region including a first sub photoelectric conversion region and a second sub photoelectric conversion region;
a pixel isolation structure defining the unit pixel region, extending in a vertical direction in the substrate, and extending in a first horizontal direction and a second horizontal direction;
a first insulation layer and a second insulation layer sequentially arranged on the front-side surface of the substrate;
a first dual transfer gate electrode disposed in the substrate to pass through the first insulation layer and correspond to the first sub photoelectric conversion region, in the unit pixel region;
a second dual transfer gate electrode disposed in the substrate to pass through the first insulation layer and correspond to the second sub photoelectric conversion region, in the unit pixel region;
a plurality of conductive vias passing through the second insulation layer and contacting each of the first dual transfer gate electrode and the second dual transfer gate electrode; and
a color filter and a lens each disposed on the backside surface of the substrate, wherein
the first dual transfer gate electrode comprises a first sub transfer gate electrode and a second sub transfer gate electrode adjacent thereto in the substrate,
the second dual transfer gate electrode comprises a third sub transfer gate electrode and a fourth sub transfer gate electrode adjacent thereto in the substrate,
the first dual transfer gate electrode and the second dual transfer gate electrode comprise a material having an etch selectivity with the first insulation layer,
a lower surface of each of the first sub transfer gate electrode, the second sub transfer gate electrode, the third sub transfer gate electrode, and the fourth sub transfer gate electrode is disposed at a vertical level which is lower than the front-side surface of the substrate, and
an upper surface of each of the first sub transfer gate electrode, the second sub transfer gate electrode, the third sub transfer gate electrode, and the fourth sub transfer gate electrode is disposed at a vertical level which is higher than the front-side surface of the substrate.

19. The image sensor of claim 18, wherein the first insulation layer comprises silicon nitride, and
the first dual transfer gate electrode and the second dual transfer gate electrode comprise polysilicon.

20. The image sensor of claim 18, wherein the plurality of conductive vias comprise one or more conductive vias contacting the first sub transfer gate electrode and the second sub transfer gate electrode in common or respectively.
